(19) United States
(12) Patent Application Publication
(10) Pub. No.: US 2026/0277120 A1
(43) Pub. Date: Sep. 17, 2026

(54) METHOD AND APPARATUS FOR DETERMINING IMAGE STRUCTURE

(71) Applicant: INSTITUTE OF MICROELECTRONICS, CHINESE ACADEMY OF SCIENCES, Beijing (CN)

(72) Inventors: Yajuan Su, Beijing (CN); Pengyu Ren, Beijing (CN); Yayi Wei, Beijing (CN); Huwen Ding, Beijing (CN); Xiaojing Su, Beijing (CN); Libin Zhang, Beijing (CN)

(21) Appl. No.: 19/211,823

(22) Filed: May 19, 2025

(30) Foreign Application Priority Data
Mar. 14, 2025 (CN) 202510305789.X

(51) Int. Cl. G03F 7/00

(52) U.S. Cl. CPC G03F 7/706839; G03F 7/70504; G03F 7/706837

(57) ABSTRACT

A method and an apparatus for determining an imaging structure. The method comprises: determining candidate simulation parameters for an imaging model, where the imaging model comprises a light source, an imaging structure, and a patterned mask, the imaging structure comprises a metal layer and a photoresist layer, and the candidate simulation parameters comprises M first candidate parameters for the imaging structure and N second candidate parameters for the patterned mask; performing simulation on the imaging model using all parameter combinations to obtain M×N results of imaging quality; determining, for each first candidate parameter, a quantity of the results obtained using such first candidate parameter and greater than an image quality threshold; determining a target first candidate parameter from the M first candidate parameters according to the quantity for each first candidate parameter; and preparing a real imaging structure according to the target first candidate parameter.

The present application claims the priority to Chinese Patent Application No. 202510305789.X, titled “METHOD AND APPARATUS FOR DETERMINING IMAGE STRUCTURE,” filed on Mar. 14, 2025 with the China National Intellectual Property Administration, the content of which is incorporated herein by reference.

### TECHNICAL FIELD

The present disclosure relates to the technical field of photolithography, and in particular to a method and an apparatus for determining an imaging structure.

### BACKGROUND

Plasma lithography is also called surface plasma lithography. There are three main types of plasma lithography, i.e., interreference lithography, imaging lithography, and direct writing lithography. The interference lithography and the imaging lithography utilize masks, while the direct writing lithography is maskless. During the plasma lithography, surface plasmon polaritons (SPPs) are excited to amplify evanescent waves at the mask through resonation. Hence, the evanescent waves participate in the imaging process, which breaks through the diffraction limit of the traditional projection-type lithography. Plasma lithography thus provides a reliable technical approach for realizing nanolithography techniques having a low cost, applicable to a large area, and of high efficiency. In conventional technology, appropriate imaging structures shall be provided for different masks to ensure good lithography effect. Hence, a respective imaging structure needs to be prepared for each mask, which not only wastes time but also increases the cost of lithography.

### SUMMARY

A method and an apparatus for determining an imaging structure is provided according to embodiments of the present disclosure. The imaging structure having good compatibility and robustness in lithography can be determined quickly and accurately, and costs of the lithography can be reduced.

In an aspect of embodiments of the present disclosure, a method for determining an imaging structure is provided. The method comprises: determining candidate simulation parameters for an imaging model, where the imaging model comprises a light source, an imaging structure, and a patterned mask, the imaging structure comprises a metal layer and a photoresist layer, the light source is configured to emit light for forming an image on the photoresist layer through the patterned mask and the metal layer, the candidate simulation parameters comprises M first candidate parameters for the imaging structure and N second candidate parameters for the patterned mask, and both M and N are integers greater than 1; performing simulation on the imaging model using all parameter combinations to obtain M×N results of imaging quality, where each of the parameter combinations comprises a respective one of the M first candidate parameters and a respective one of the N second candidate parameters; determining, for each of the M first candidate parameters, a quantity of the results of imaging quality that are obtained using said first candidate parameter and are greater than an image quality threshold; determining a target first candidate parameter from the M first candidate parameters according to the quantity for each of the M first candidate parameters; and preparing a real imaging structure according to the target first candidate parameter.

In an embodiment, each result of the results of imaging quality is light intensity contrast, and the light intensity contrast is obtained according to a maximum light intensity in the photoresist layer and a minimum light intensity at the photoresist layer.

In an embodiment, the image quality threshold when the photoresist layer is a positive photoresist is greater than the image quality threshold when the photoresist layer is a negative photoresist.

In an embodiment, the method further comprises: calculating a first optical transfer function (OTF) curve of the imaging structure having the target first candidate parameter; and verifying the imaging structure having the target first candidate parameter according to the first OTF curve.

In an embodiment, verifying the imaging structure having the target first candidate parameter according to the first OTF curve comprises: determining the imaging structure having the target first candidate parameter is applicable to the real imaging structure, in response to: the first OTF curve being higher than a second OTF curve of the imaging structure having a first candidate parameter, which is other than the target candidate parameter among the M first candidate parameters, throughout a section representing a propagating wave; the first OTF curve being higher than the second OTF curve throughout a section representing an evanescent wave; and a range of the first OTF curve which is in the section representing the evanescent wave and is within a target amplitude range being greater than a preset bandwidth.

In an embodiment, each of the M candidate parameters comprises one or both of a thickness of the metal layer and a thickness of the photoresist layer, and each of the N candidate parameters comprises a first width of a transmissive portion and a second width of a non-transmissive portion.

In another aspect of embodiments of the present disclosure, an apparatus for determining an imaging structure is provided. The apparatus comprises: a first determining module, configured to determine candidate simulation parameters for an imaging model, where the imaging model comprises a light source, an imaging structure, and a patterned mask, the imaging structure comprises a metal layer and a photoresist layer, the light source is configured to emit light for forming an image on the photoresist layer through the patterned mask and the metal layer, the candidate simulation parameters comprises M first candidate parameters for the imaging structure and N second candidate parameters for the patterned mask, and both M and N are integers greater than 1; a calculating module, configured to perform simulation on the imaging model using all parameter combinations to obtain M×N results of imaging quality, where each of the parameter combinations comprises a respective one of the M first candidate parameters and a respective one of the N second candidate parameters; a second determining unit, configured to determine, for each of the M first candidate parameters, a quantity of the results of imaging quality that are obtained using said first candidate parameter and are greater than an image quality threshold; a third determining module, configured to determine a target first candidate parameter from the M first candidate parameters according to the quantity for each of the M first candidate parameters; and a preparing module, configured to prepare a real imaging structure according to the target first candidate parameter.

In another aspect of embodiments of the present disclosure, an electronic device is provided, where the electronic device comprises a processor and a memory, the memory is configured to store computer-readable instructions, and the computer-readable instructions when executed by the processor enable the electric device to perform any foregoing method.

In another aspect of embodiments of the present disclosure, a computer-readable storage medium is provided, where the computer-readable storage medium stores computer-readable instructions, and the computer-readable instructions when executed by a processor enable an electric device to perform any foregoing method.

Herein the method and the apparatus for determining the imaging structure are provided. The candidate simulation parameters are determined for the imaging model, where the imaging model comprises the light source, the imaging structure, and the patterned mask, the imaging structure comprises the metal layer and the photoresist layer, the light source is configured to emit light for forming the image on the photoresist layer through the patterned mask and the metal layer, the candidate simulation parameters comprises the M first candidate parameters for the imaging structure and the N second candidate parameters for the patterned mask, and both M and N are integers greater than 1. The imaging structure varies under different first candidate parameters, and the patterned mask varies under different second candidate parameters. The simulation is performed on the imaging model using all parameter combinations to obtain the M×N results of imaging quality, where each of the parameter combinations comprises the respective one of the M first candidate parameters and the respective one of the N second candidate parameters. That is, the first candidate parameters and the second candidate parameter are combined pairwise, and the imaging model under each combination is simulated to obtain the results reflecting imaging quality on the photoresist layer. The different first candidate parameters serve as a basis for evaluating which imaging structure has better lithography compatibility. That is, for each of the M first candidate parameters, the quantity of the results of imaging quality that are obtained using such first candidate parameter and are greater than an image quality threshold is determined. Hence, it is counted how many second candidate parameters can achieve a qualified imaging effect, i.e., a good lithography effect, when combined with a certain first candidate parameter. The more second candidate parameters there are for a certain first candidate parameter, the better the lithography compatibility and robustness such first candidate parameter can achieve. The target first candidate parameter is determined from the M first candidate parameters according to the quantity for each of the M first candidate parameters, and the real imaging structure is prepared according to the target first candidate parameter. The imaging structure corresponding to the target first candidate parameter is an imaging structure having good compatibility and robustness, that is, it can achieve good imaging in lithography for a variety of masks. Hence, the method provided herein can determine an imaging structure with good lithography compatibility and robustness quickly and accurately through simulation on various masks and various imaging structures. The prepared imaging structure is capable to adapt to a variety of masks while achieving good imaging effects, and it is not necessary to customize a separate imaging structure for each mask. Mass production is facilitated with low cost of lithography.

### BRIEF DESCRIPTION OF THE DRAWINGS

Hereinafter drawings to be applied in embodiments of the present disclosure or in conventional technology are briefly described, in order to clarify illustration of technical solutions according to embodiments of the present disclosure or in conventional technology. Apparently, the drawings in the following descriptions are only some embodiments of the present disclosure, and other drawings may be obtained by those skilled in the art based on the provided drawings without exerting creative efforts.

FIG. 1 is a schematic diagram of a flow chart of a method for determining an imaging structure according to an embodiment of the present disclosure.

FIG. 2 is a schematic structural diagram of an imaging model according to an embodiment of the present disclosure.

FIG. 3 is schematic graphs of OTF curves of imaging structures having target candidate parameters that meet a requirement on light intensity contrast according to an embodiment of the present disclosure.

FIG. 4 is a structural block diagram of an apparatus for determining an imaging structure according to an embodiment of the present disclosure.

FIG. 5 is a structural diagram of an electronic device according to an embodiment of the present disclosure.

### DETAILED DESCRIPTION OF THE EMBODIMENTS

Hereinafter specific embodiments of the present disclosure are described in detail in conjunction with the drawings to clarify and elucidate objectives, features, and advantages of the present disclosure.

Various details are set forth in following embodiments to facilitate thorough understanding of the present disclosure, and the present disclosure may be implemented in manners other than those described herein. Those skilled in the art may obtained these manners by analogy without departing from the concepts of the present disclosure. Therefore, the present disclosure is not limited to the following embodiments.

Herein the embodiments are described in detail in conjunction with the drawings. In a cross-sectional diagram, a part of a device structure may not be enlarged to scale for the sake of clarity. The schematic diagrams are exemplary and do not limit the scope of protection of the present disclosure. In practice, three-dimensional dimensions, e.g., length, width, and depth, shall be configured.

In conventional technology, appropriate imaging structures shall be provided for different masks to ensure good lithography effect. Hence, a respective imaging structure needs to be prepared for each mask, which not only wastes time but also increases the cost of lithography.

A method and an apparatus for determining an imaging structure is provided according to embodiments of the present disclosure. An imaging structure with good lithography compatibility and robustness can be determined quickly and accurately through simulation on various masks and various imaging structures. The determined imaging structure is capable to adapt to a variety of masks while achieving good imaging effects, and it is not necessary to customize a separate imaging structure for each mask. Mass production is facilitated with low cost of lithography.

The method provided herein may be executed by an electronic device, and the electronic device may be a terminal device or a server. The server may be an independent physical server, may be a server cluster or a distributed system that comprises multiple physical servers, and may be a cloud server providing cloud computing services. The terminal device includes, but is not limited to a mobile phone, a computer, an intelligent voice interaction device, a smart home appliance, a vehicle-mounted terminal, and the like. The terminal device and the server may be directly or indirectly connected via wired or wireless communication. Herein the electronic device is not limited to the above examples.

Hereinafter the method and the apparatus would be illustrated in detail in conjunction with the drawings.

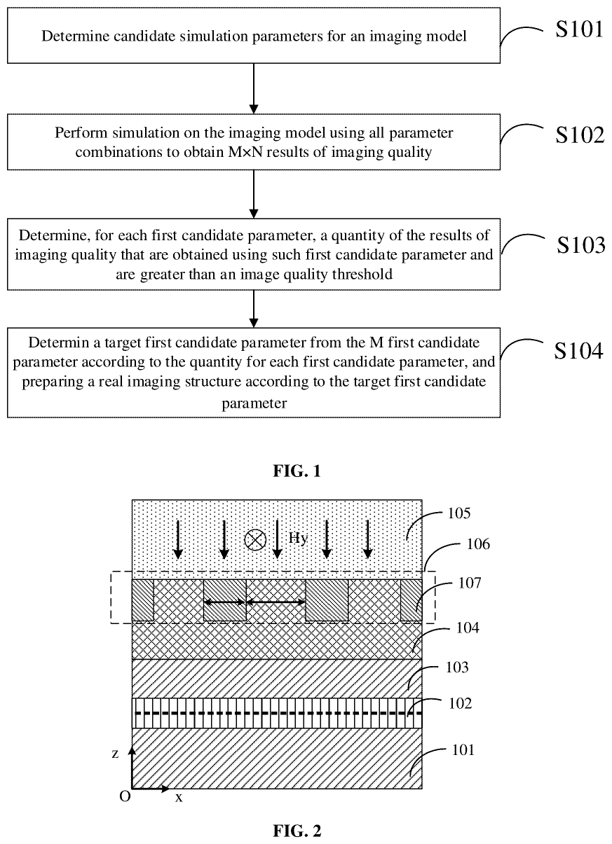

Reference is made to FIG. 1, which is a flow chart of a method for determining an imaging structure according to an embodiment of the present disclosure. The method may comprise following steps S101 to S104.

In step S101, candidate simulation parameters are determined for an imaging model.

The imaging model may be a simulation model configured to simulate a process of plasma lithography imaging. The imaging model may comprise a light source, an imaging structure, and a patterned mask. The imaging structure may comprise a metal layer and a photoresist layer. The metal layer may be a silver (Ag) layer, and the photoresist layer may be a praseodymium (Pr) layer. The imaging structure may comprise other film layers, for example, a polymethyl methacrylate (PMMA) layer located at a side of the metal layer away from the photoresist layer.

The light source is configured to emit light, and the light is configured to form an image on the photoresist layer via the patterned mask and the metal layer. That is, the light emitted by the light source is incident on the patterned mask that has a transmissive portion and a non-transmissive portion. The light incident on the imaging structure passes the transmissive portion, hence the pattern of the mask is transmitted to the photoresist layer, and the image is formed on the photoresist layer. Specifically, the light emitted by the light source interacts with free electrons at a surface of the metal layer, such that plasmon polaritons are excited at the surface to generate an evanescent wave at an interface between the metal layer and the photoresist layer. Thereby, the photoresist layer is exposed to bear the image.

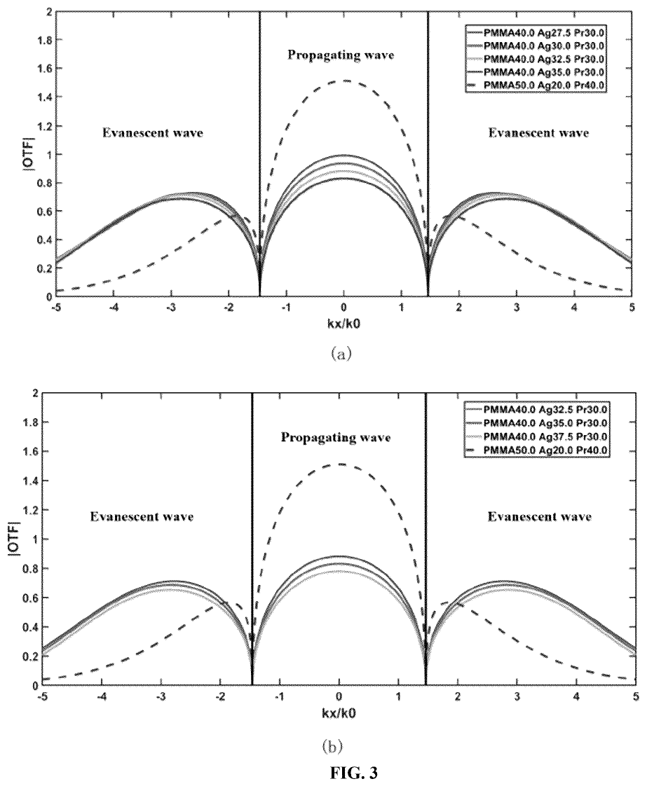

As an example, the imaging model may be a superlens imaging model. Reference is made to FIG. 2, which is a schematic structural diagram of an imaging model according to an embodiment of the present disclosure. The imaging model comprises an imaging structure and a mask. The imaging structure comprises a reflective layer 101, a photoresist layer 102, a metal layer 103, and a PMMA layer 104, which are stacked bottom-up according to the above-listed sequence. The mask 106 comprises a non-transmissive portion 107 and a transmissive portion which is also made of PMMA. The transmissive portion is indicated by the light-shaded horizontal arrow as shown in FIG. 2, and the non-transmissive portion is indicated by the dark-shaded horizontal arrow as shown in FIG. 2. A material of the non-transmissive portion may be chromium (Cr). A substrate layer 105 may be arranged on the mask 106, and the substrate layer 105 may be made of glass. Materials of the reflective layer 101 and the metal layer 103 may be the same or different. The light source may emit a monochromatic transverse magnetic (TM) wave with a wavelength of 365 nm, and the light is normally incident on the imaging model. In addition, the imaging model can be constructed using existing simulation tools, which will not be repeated.

The imaging model is configured with candidate simulation parameters. The candidate simulation parameters may comprise first candidate parameters for the imaging structure and second candidate parameters for the mask. M first candidate parameters and N second candidate parameters may be configured for subsequent simulation calculations to determine an imaging structure with good lithography compatibility. That is, the candidate simulation parameters comprise M first candidate parameters and N second candidate parameters, and both M and N are integers greater than 1. Different imaging structures can be obtained using different first candidate parameters, and different imaging structures can be obtained using different second candidate parameters.

In an embodiment, the first candidate parameter comprises one or both of a thickness of the metal layer and a thickness of the photoresist layer. The second candidate parameter may comprise a first width of the transmissive portion and a second width of the non-transmissive portion.

In the imaging structure, thickness of a film has a significant impact on an imaging effect, and a pattern of the mask, that is, the respective widths of the transmissive and the non-transmissive portions, also affects the imaging. Hence, the thickness of the metal layer and/or the photoresist layer serve as the first candidate parameter, and the respective widths of the transmissive and the non-transmissive portions serve as the second candidate parameters, such that a structural difference of the imaging structure and a structural difference of the mask can be enlarged. Thus, a large number of distinct candidate imaging structures can be provided for subsequent determination of the image structure having good lithography compatibility.

Reference is made to Table 1, which shows sets of candidate simulation parameters. It is taken as an example that the imaging model is the superlens imaging model, the metal layer is a top Ag layer, and the photoresist layer is a Pr layer.

TABLE 1

| | Range (min, | |
|---|---|---|
| Type | step-size, max) | Quantity |
| Thickness of PMMA layer | 40, 2.5, 55 | 7 |
| Thickness of top Ag layer | 10, 2.5, 50 | 17 |
| Thickness of Pr layer | 30, 2.5, 45 | 7 |
| Width of | 20, 10, 150 | 14 |
| transmissive portion | | |
| Width of | 20, 10, 150 | 14 |
| non-transmissive portion | | |

The range denotes how the thickness of a corresponding layer varies. The thickness of the PMMA layer is taken as an example, in which the thickness varies from 40 nm to 55 nm with a step size of 2.5 nm, and hence a quantity of values of the thickness is 7. As shown in Table 1, a quantity of the candidate imaging structures (or the first candidate parameters) is equal to 7×17×7=833, and a quantity of the candidate masks (or the second candidate parameters) is equal to 14×14=196. Every candidate imaging structure can be combined with every candidate mask to obtain a version of the image model, and simulation is performed on such version of the image model.

In step S102, simulation is performed on the imaging model using all parameter combinations to obtain M×N results of imaging quality, where each parameter combination comprises a respective first candidate parameter and a respective second candidate parameter.

Each parameter combination corresponds to a respective version of the image model. There are M×N parameter combination since there are M first candidate parameters and N second candidate parameters. The version of the imaging model corresponding to each parameter combination is subject to simulation to obtain the corresponding result of imaging quality. Hence, a total of M×N results of image quality are obtained. The result of imaging quality is a parameter characterizing quality of lithography imaging. As an example, the parameter may be light intensity, light intensity contrast, or a process window. The result of imaging quality also reflects the imaging quality at the photoresist layer.

In an embodiment, the result of imaging quality is a light intensity contrast. The light intensity contrast is determined according to a maximum light intensity and a minimum light intensity at the photoresist layer.

The light intensity contrast may serve as measurement of the imaging quality because it is highly correlated with the imaging quality. The light intensity contrast may refer to light intensity contrast at a middle position (as indicated by a dotted line in FIG. 2) of the photoresist layer. Alternatively, it may be light intensity contrast at an upper surface or a lower surface of the photoresist layer. Generally, it is more accurate to use the light intensity contrast at the middle position.

The light intensity contrast may be calculated according to the maximum light intensity Iₘₐₓ and the minimum light intensity Iₘᵢₙ at the photoresist layer through (Iₘₐₓ−Iₘᵢₙ)/(Iₘₐₓ+Iₘᵢₙ).

In step S103, for each first candidate parameter, a quantity of the results of imaging quality that are obtained using such first candidate parameter and are greater than an image quality threshold is determined.

The imaging quality threshold may be regarded as the result of imaging quality when the imaging quality just meets the standard. When the result of imaging quality is the light intensity contrast, the imaging quality threshold is a light-intensity-contrast (LIC) threshold.

The different first candidate parameters serve as a basis for evaluating which imaging structure has better lithography compatibility. Each candidate imaging structure is combined with various candidate masks separately in simulation. Hence, it can be determined whether the result of imaging quality obtained under its combination with each candidate mask is greater than the imaging quality threshold, and the total number of qualified candidate masks, i.e., those in the combinations of which the result is greater than the imaging quality threshold, can be counted. In other words, the quantity of the qualified second candidate parameters are determined for each first candidate parameter. Thus, it is determined how many second candidate parameters lead to a qualified imaging effect, i.e., a good lithography effect, when combining with a certain first candidate parameter. The more the qualified candidate masks are determined for a certain candidate imaging structure, the better the lithography compatibility and robustness of such imaging structure is.

Hereinafter light intensity contrast is taken as an example for illustrating the results of imaging quality. Reference is made to Table 2, which shows the quantities of the qualified second candidate parameters (i.e., the qualified candidate masks) for each candidate imaging structure under different LIC thresholds.

TABLE 2

| Candidate | | |
|---|---|---|
| imaging structure | LIC > 0.2 | LIC > 0.4 |
| PMMA50-Ag20-Pr40 | 126 | 94 |
| PMMA40-Ag27.5-Pr30 | 190 | 178 |
| PMMA40-Ag30-Pr30 | 190 | 183 |
| PMMA40-Ag32.5-Pr30 | 190 | 187 |
| PMMA40-Ag35-Pr30 | 190 | 187 |
| PMMA40-Ag37.5-Pr30 | 189 | 187 |

The name in the column of “candidate imaging structure” uses numbers to indicate thickness of each film. For example, “PMMA50-Ag20-Pr40” represents that the thickness of the PMMA layer is 50 nm, the thickness of the Ag layer is 20 nm, and the thickness of the Pr layer is 40 nm. In Table 2, PMMA50-Ag20-Pr40 is an unoptimized candidate imaging structure, and the other candidate imaging structures are optimized imaging structures (i.e., those having better imaging quality). Among them, 0.2 and 0.4 are both imaging quality thresholds. LIC>0.2 is taken as an example. For the unoptimized candidate imaging structure, the quantity of the qualified second candidate parameters (i.e., the qualified candidate masks) is 126, which means that 126 out of 196 candidate masks can achieve good compatibility. The quantities of the qualified second candidate parameters for the four optimized imaging structures are all 190, which means that 190 out of 196 candidate masks can achieve good compatibility. Hence, the optimization improves lithography compatibility and robustness and of the imaging structure by 50.79%. LIC>0.4 is taken as another example. The quantity of the qualified second candidate parameters for the unoptimized candidate imaging structure is 94, while the quantities of the qualified second candidate parameters for three optimized candidate imaging structure is 187. Hence, the optimization improves lithography compatibility and robustness and of the imaging structure by 98.94%. The compatibility of the imaging structure with respect to the mask is greatly improved through the optimization, and the compatibility is especially good under thin PMMA layer and thin Pr layer.

In an embodiment, the image quality threshold when the photoresist layer is a positive photoresist is greater than the image quality threshold when the photoresist layer is a negative photoresist.

As for the positive photoresist, a region irradiated by light becomes more soluble and thus can be removed during development, and hence a pattern identical to the pattern of the mask is obtained. As for the negative photoresist, a region irradiated by light becomes less soluble, and hence a pattern complementary to the pattern of the mask is obtained. A larger LIC threshold, such as 0.4, may be selected for the positive photoresist. A smaller LIC threshold, such as 0.2, may be selected for the negative photoresist.

The photosensitizer in the positive photoresist absorbs energy of light to break polymer molecular chains. A higher light intensity contrast threshold ensures that the positive photoresist is more soluble, and hence the photolithography pattern is shaper, achieving higher resolution.

In step S104, a target first candidate parameter is determined from the M first candidate parameters according to the quantity for each first candidate parameter. A real imaging structure may be prepared (e.g., fabricated) according to the target first candidate parameter.

More qualified candidate masks indicate better lithography compatibility of the corresponding candidate imaging structure, and such candidate imaging structure is more likely to serve as a basis of the real imaging structure. According to the quantity of qualified candidate masks, target first candidate parameter(s) leading to better compatibility can be selected from the M first candidate parameters. The imaging structure corresponding to the target first candidate parameters may serve as the basis of the real imaging structure.

As an example, the quantity of qualified candidate masks is compared with 180. In a case that the quantity of qualified candidate masks for a certain first candidate parameter is greater than 180, the first candidate parameter is determined as the target first candidate parameter. Otherwise, it is not determined as the target first candidate parameter. Thereby, the candidate imaging structure(s) having good compatibility and robustness with respect to various candidate masks can be picked out.

The imaging structure corresponding to the target first candidate parameter has good compatibility and robustness, and hence it can achieve good lithography across various masks. The method provided herein can determine an imaging structure with good lithography compatibility and robustness quickly and accurately through simulation on various masks and various imaging structures. The prepared imaging structure is capable to adapt to a variety of masks while achieving good imaging effects, and it is not necessary to customize a separate imaging structure for each mask. Mass production is facilitated with low cost of lithography.

In an embodiment, the method further comprises steps S105 and S106.

In step S105, a first optical transfer function (OTF) curve of the imaging structure having the target first candidate parameter is calculated.

In step S106, the imaging structure having the target first candidate parameter is verified according to the first OTF curve.

The OTF curve of the candidate imaging structure may be calculated through a simulation tool. Reference is made to FIG. 3, in which sub-figure (a) is a schematic graph of the OTF curve of the candidate imaging structure having the target first candidate parameter when the LIC threshold is set to 0.2, and (b) is a schematic graph of the OTF curve of the candidate imaging structure having the target first candidate parameter when the LIC threshold is set to 0.4. A horizontal axis represents spatial frequency, and a vertical axis represents |OTF|. In FIG. 3, the dashed line represents the OTF curve of an unoptimized candidate imaging structure, while the solid lines represent the OTF curves of optimized imaging structures.

Different imaging structures have different OTF curves, and the OTF curve of an imaging structure with better compatibility is characterized with smaller amplitude in a section (i.e., a frequency range) representing a propagating wave and larger amplitude in a section representing an evanescent wave. Hence, the candidate imaging structure having the target first candidate parameter may be verified according to amplitude of the OTF curve. In a case that the candidate imaging structure not only has a large number of qualified candidate masks but also an OTF curve of which the amplitude reflects good compatibility, the target imaging structure has been successfully verified.

In summary, the OTF curve may serve as a criterion for verifying whether the candidate imaging structure having the target first candidate parameter really has good compatibility. The verification using the OTF curve has a physical basis and thus can improve accuracy of the final real imaging structure.

In an embodiment, step S106 comprises following sub-steps. The imaging structure having the target first candidate parameter is determined to be applicable to the real imaging structure, in a case that: a) the first OTF curve is lower than a second OTF curve of the imaging structure having a first candidate parameter, which is other than the target candidate parameter among the M first candidate parameters, throughout a section representing a propagating wave, b) the first OTF curve is higher than the second OTF curve throughout a section representing an evanescent wave, and c) a range of the first OTF curve which is in the section representing the evanescent wave and is within a target amplitude range is greater than a preset bandwidth.

From the perspective of spatial frequency, geometric dimensions of the mask determine a range of spatial frequency. The OTF determines which spatial frequency can be transferred to an image plane in one aspect and determines efficiency of the transfer in another aspect.

The optimized imaging structure, which has good compatibility, is characterized in that the amplitude in the section of the propagation wave is decreased, i.e., smaller than that of the unoptimized imaging structure, and the amplitude in the section of the evanescent wave is increased. Hence, for the candidate imaging structure having the target first candidate parameter, it is determined whether the first OTF curve is lower than the second OTF curve throughout the section of the propagation wave and whether the first OTF curve is higher than the second OTF curve throughout the section of the evanescent wave. The second OTF may be the OTF of the unoptimized imaging structure, which has poorer compatibility.

In addition, in the first OTF curve of the optimized imaging structure, the bandwidth of a range having high amplitude is larger in the section of the evanescent wave. That is, a larger range of spatial frequency has large amplitude. In the second OTF curve of the unoptimized imaging structure, the bandwidth of a range having high amplitude is smaller in the section of the evanescent wave. Hence, for the candidate imaging structure having the target first candidate parameter, it is determined whether a range of the first OTF curve which is in the section representing the evanescent wave and is within the target amplitude range is greater than a preset bandwidth. The target amplitude range may be a large amplitude range, for example, around |OTF|=0.6 as shown in FIG. 3. The preset bandwidth is a preset range of spatial frequency.

In a case that the first OTF curve is lower than the second OTF curve in the section of the propagating wave, the first OTF curve is higher than the second OTF curve in the section of the evanescent wave, and the range of the first OTF curve which is in the section of the evanescent wave and is within the target amplitude range is greater than the preset bandwidth, the candidate imaging structure having the target first candidate parameter is determined to have good compatibility and thus determined to be successfully verified.

The propagating wave carries general information of the pattern of the mask, and the evanescent wave carries information on details of the pattern of the mask. Hence, high amplitude of the optimized imaging structure in the section of the evanescent wave indicates the details of the pattern can be transferred to the photoresist layer with high efficiency, and large bandwidth having the high amplitude indicates that more details of the pattern can be transferred. In such case, the candidate imaging structure having the target first candidate parameter can achieve better lithography effects for a variety of masks, i.e., have good compatibility.

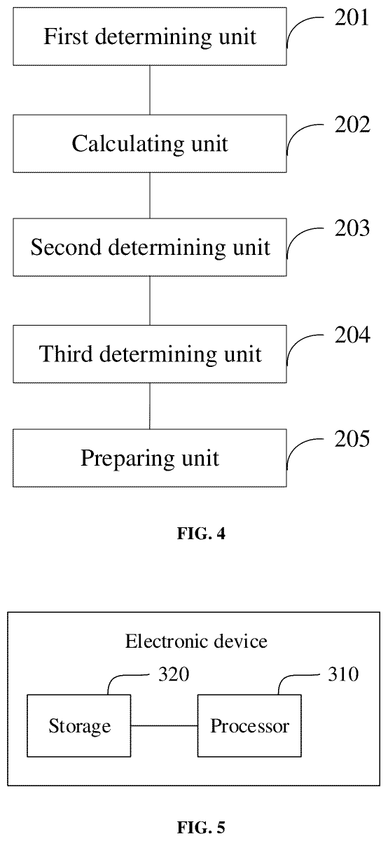

On a basis of the above method, an apparatus for determining an imaging structure is further provided according to embodiments of the present disclosure. Reference is made to FIG. 4, which is a structural block diagram of an apparatus for determining an imaging structure according to embodiments of the present disclosure. The apparatus comprises a first determining module 201, a calculating module 202, a second determining module 203, a third determining module 204, and a preparing module 205.

The first determining module 201 is configured to determine candidate simulation parameters for an imaging model, where the imaging model comprises a light source, an imaging structure, and a patterned mask, the imaging structure comprises a metal layer and a photoresist layer, the light source is configured to emit light for forming an image on the photoresist layer through the patterned mask and the metal layer, the candidate simulation parameters comprises M first candidate parameters for the imaging structure and N second candidate parameters for the patterned mask, and both M and N are integers greater than 1.

The calculating module 202 is configured to perform simulation on the imaging model using all parameter combinations to obtain M×N results of imaging quality, where each of the parameter combinations comprises a respective one of the M first candidate parameters and a respective one of the N second candidate parameters.

The second determining unit 203 is configured to determine, for each of the M first candidate parameters, a quantity of the results of imaging quality that are obtained using said first candidate parameter and are greater than an image quality threshold.

The third determining module 204 is configured to determine a target first candidate parameter from the M first candidate parameters according to the quantity for each of the M first candidate parameter.

The preparing module 205 is configured to prepare a real imaging structure according to the target first candidate parameter.

In an embodiment, each result of the results of imaging quality is light intensity contrast, and the light intensity contrast is obtained according to a maximum light intensity in the photoresist layer and a minimum light intensity at the photoresist layer.

In an embodiment, the image quality threshold when the photoresist layer is a positive photoresist is greater than the image quality threshold when the photoresist layer is a negative photoresist.

In an embodiment, the apparatus further comprises a calculating unit and a verifying unit. The calculating unit is configured to calculate an OTF curve of the imaging structure having the target first candidate parameter. The verifying module is configured to verify the imaging structure having the target first candidate parameter according to the OTF curve.

In an embodiment, the verifying module is configured to determine the imaging structure having the target first candidate parameter is applicable to the real imaging structure, in response to: the first OTF curve being higher than a second OTF curve of the imaging structure having a first candidate parameter, which is other than the target candidate parameter among the M first candidate parameters, throughout a section representing a propagating wave; the first OTF curve being higher than the second OTF curve throughout a section representing an evanescent wave; and a range of the first OTF curve which is in the section representing the evanescent wave and is within a target amplitude range being greater than a preset bandwidth.

In an embodiment, each of the M candidate parameters comprises one or both of a thickness of the metal layer and a thickness of the photoresist layer, and each of the N candidate parameters comprises a first width of a transmissive portion and a second width of a non-transmissive portion.

An electronic device is further provided according to an embodiment of the present disclosure. Reference is made to FIG. 5, which is a structural diagram of an electronic device according to an embodiment of the present disclosure. The electronic device comprises a processor 310 and a memory 320.

The memory 320 is used to store computer-readable instructions.

The computer-readable instructions when executed by the processor enable the electric device to perform the method according to any foregoing embodiment.

The electronic device may include a terminal device or a server, and the foregoing apparatus may be configured in the electronic device.

A computer-readable storage medium is further provided according to an embodiment of the present disclosure. The computer-readable storage medium stores computer-readable instructions, and the computer-readable instructions when executed by a processor enable an electric device to perform any foregoing method.

All or part of the steps of the above method embodiments may be implemented by a program instructing hardware, and the program may be stored in a computer-readable storage medium. When the program is executed, the steps of the above method embodiment are implemented. The storage medium may be at least one of: read-only memory (ROM), RAM, magnetic disk, optical disk, or other media that can store program codes.

The embodiments of the present disclosure are described in a progressive manner, and each embodiment places emphasis on the difference from other embodiments. Therefore, one embodiment can refer to other embodiments for the same or similar parts. Since the apparatuses disclosed in the embodiments correspond to the methods disclosed in the embodiments, the description of the apparatuses is simple, and reference may be made to the relevant part of the methods.

The foregoing embodiments are only preferred embodiments of the present disclosure, and do not limit the present disclosure in any form. The preferred embodiments according to the disclosure are disclosed above and are not intended to limit the present disclosure. With the method and technical content disclosed above, those skilled in the art can make some variations and improvements to the technical solutions of the present disclosure or make some equivalent variations on the embodiments without departing from the scope of technical solutions of the present disclosure. All simple modifications, equivalent variations and improvements made based on the technical essence of the present disclosure without departing the content of the technical solutions of the present disclosure fall within the protection scope of the technical solutions of the present disclosure.

1. A method for determining an imaging structure, comprising:
determining candidate simulation parameters for an imaging model, wherein the imaging model comprises a light source, an imaging structure, and a patterned mask, the imaging structure comprises a metal layer and a photoresist layer, the light source is configured to emit light for forming an image on the photoresist layer through the patterned mask and the metal layer, the candidate simulation parameters comprises M first candidate parameters for the imaging structure and N second candidate parameters for the patterned mask, and both M and N are integers greater than 1;
performing simulation on the imaging model using all parameter combinations to obtain M×N results of imaging quality, wherein each of the parameter combinations comprises a respective one of the M first candidate parameters and a respective one of the N second candidate parameters;
determining, for each of the M first candidate parameters, a quantity of the results of imaging quality that are obtained using said first candidate parameter and are greater than an image quality threshold;
determining a target first candidate parameter from the M first candidate parameters according to the quantity for each of the M first candidate parameters; and
preparing a real imaging structure according to the target first candidate parameter.

2. The method according to claim 1, wherein each result of the results of imaging quality is light intensity contrast, and the light intensity contrast is obtained according to a maximum light intensity in the photoresist layer and a minimum light intensity at the photoresist layer.

3. The method according to claim 2, wherein the image quality threshold when the photoresist layer is a positive photoresist is greater than the image quality threshold when the photoresist layer is a negative photoresist.

4. The method according to claim 1, further comprising:
calculating a first optical transfer function (OTF) curve of the imaging structure having the target first candidate parameter; and
verifying the imaging structure having the target first candidate parameter according to the first OTF curve.

5. The method according to claim 4, wherein verifying the imaging structure having the target first candidate parameter according to the first OTF curve comprises:
determining the imaging structure having the target first candidate parameter is applicable to the real imaging structure, in response to:
the first OTF curve being lower than a second OTF curve of the imaging structure having a first candidate parameter, which is other than the target candidate parameter among the M first candidate parameters, throughout a section representing a propagating wave,
the first OTF curve being higher than the second OTF curve throughout a section representing an evanescent wave, and
a range of the first OTF curve, which is in the section representing the evanescent wave and is within a target amplitude range, being greater than a preset bandwidth.

6. The method according to claim 1, wherein each of the M candidate parameters comprises one or both of a thickness of the metal layer and a thickness of the photoresist layer, and each of the N candidate parameters comprises a first width of a transmissive portion and a second width of a non-transmissive portion.

7. An apparatus for determining an imaging structure, comprising:
a first determining module, configured to determine candidate simulation parameters for an imaging model, wherein the imaging model comprises a light source, an imaging structure, and a patterned mask, the imaging structure comprises a metal layer and a photoresist layer, the light source is configured to emit light for forming an image on the photoresist layer through the patterned mask and the metal layer, the candidate simulation parameters comprises M first candidate parameters for the imaging structure and N second candidate parameters for the patterned mask, and both M and N are integers greater than 1;
a calculating module, configured to perform simulation on the imaging model using all parameter combinations to obtain M×N results of imaging quality, wherein each of the parameter combinations comprises a respective one of the M first candidate parameters and a respective one of the N second candidate parameters;
a second determining unit, configured to determine, for each of the M first candidate parameters, a quantity of the results of imaging quality that are obtained using said first candidate parameter and are greater than an image quality threshold;
a third determining module, configured to determine a target first candidate parameter from the M first candidate parameters according to the quantity for each of the M first candidate parameters; and
a preparing module, configured to prepare a real imaging structure according to the target first candidate parameter.

8. The apparatus according to claim 7, wherein each result of the results of imaging quality is light intensity contrast, and the light intensity contrast is obtained according to a maximum light intensity in the photoresist layer and a minimum light intensity at the photoresist layer.

9. An electronic device, comprising a processor and a memory, wherein:
the memory is configured to store computer-readable instructions, and
the computer-readable instructions when executed by the processor enable the electric device to perform the method according to claim 1.

10. A computer-readable storage medium, storing computer-readable instructions, wherein the computer-readable instructions when executed by a processor enable an electric device to perform the method according to claim 1.
